(19) United States
(12) Patent Application Publication
(10) Pub. No.: US 2026/0311964 A1
(43) Pub. Date: Oct. 8, 2026

(54) APPARATUS AND METHOD FOR REPAIRING DEFECT OF SEMICONDUCTOR

(71) Applicant: Tokyo Electron Limited, Tokyo (JP)

(72) Inventors: Chi-Wen CHEN, Hsinchu City (TW); Chun-Huai LI, Hsinchu City (TW)

(21) Appl. No.: 19/711,331

(22) Filed: Jun. 17, 2026

Related U.S. Application Data
(62) Division of application No. 18/058,245, filed on Nov. 22, 2022, now abandoned.

(30) Foreign Application Priority Data
Dec. 2, 2021 (TW) 110145066

(51) Int. Cl. H01J 37/317; H10P 72/10; H10W 20/00

(52) U.S. Cl. CPC H01J 37/3171; H10P 72/1916; H10P 72/1924; H10W 20/095

(57) ABSTRACT

The apparatus includes a chamber housing having an opening and a plurality of heating devices, a gate component, a first gas-intake pipe configured to introduce a reaction gas to the first chamber and a first exhaust pipe configured to release first gas including reaction gas and second gas not including the reaction gas from the first chamber. The gate component includes a main body, a first flange, a first chamber, which is defined by an upper surface of the main body, an upper surface of the first flange and the inner surface of the chamber housing, a first sealing, a second flange, a second chamber and a second sealing, which is defined by the sidewall of the main body, a lower surface of the first flange, an upper surface of the second flange and the inner surface of the chamber housing.

### CROSS-REFERENCE TO RELATED APPLICATION

This patent application is a divisional application of U.S. Patent Application No. 18/058,245, filed on Nov. 22, 2022, which is based on and claims priority pursuant to 35 U.S.C. §119(a) to Taiwan Application Serial Number 110145066, filed on Dec. 2, 2021, which is herein incorporated by reference.

### BACKGROUND

### Field of Invention

The present invention relates to an apparatus and a method of repairing defect of a semiconductor. More particularly, the present invention relates to an apparatus and a method of repairing defect of a semiconductor performed in high pressure.

### Description of Related Art

In a manufacturing process of semiconductor wafers, one of the important reasons for influencing product yield is defect of the wafers. First, dimension of integrated circuit keep reduce, and processes such as film-formation, etching and rinsing cause defect within and/or on a surface of the semiconductor. Thereby, wafer defects are problems needed to be considered. Additionally, with development of 5G and electric vehicle, requirement for new optoelectronic devices, power devices, and radio frequency devices increases dramatically, thus driving application of wide bandgap semiconductor material (e.g., SiC, GaN, and GaAs). However, since the wide bandgap semiconductor material tends to have defect in epitaxy and processes, the devices may have problems of degradation of performance and reduction of reliability.

Conventional method of repairing defects of a semiconductor is performed in front end of process by introducing hydrogen in high-temperature furnace tube with temperature greater than 800° C to anneal the semiconductor. However, if the wafer with deposited metal layer thereon is performed annealing, the temperature greater than 800° C may melt the metal. Therefore, the temperature of about 400° C may be used to perform annealing, and then the repairing effect is far inferior to the repairing effect in condition of high temperature.

Therefore, it is needed to provide an apparatus and a method of repairing defect of a semiconductor to replace the conventional method of using high-temperature furnace tube to perform annealing and achieve performing defect repairing affectively at a lower temperature.

### SUMMARY

According to the aspect of the present invention, providing an apparatus includes a chamber housing, a gate component, a first gas-intake pipe and a first exhaust pipe. The chamber housing has an opening and a plurality of heating devices. The gate component is disposed at the opening. The gate component includes a main body, a first flange, a first chamber, a first sealing element, a second flange, a second chamber and a second sealing element. The first flange is disposed between a sidewall of the main body and an inner surface of the chamber housing. The first chamber is defined by an upper surface of the main body, an upper surface of the first flange and the inner surface of the chamber housing. The first chamber is configured to accommodate at least a semiconductor element. The first sealing element is disposed at the upper surface of the first flange. The second flange is disposed below the first flange between the sidewall of the main body and the inner surface of the chamber housing. The second chamber is defined by the sidewall of the main body, a lower surface of the first flange, an upper surface of the second flange and the inner surface of the chamber housing. The second chamber is not overlapping with the heating devices in a plan view. The second sealing element is disposed at the upper surface of the second flange. The first gas-intake pipe is configured to introduce a reaction gas to the first chamber. The first exhaust pipe is configured to release first gas including the reaction gas and second gas not including the reaction gas from the first chamber.

According to an embodiment of the present invention, the gate component further comprises a third sealing element disposed at the lower surface of the first flange.

According to an embodiment of the present invention, the apparatus further comprises a second gas-intake pipe which is configured to introduce incombustible gas to the second chamber. The apparatus further comprises second exhaust pipe which is configured to release third gas including the incombustible gas and fourth gas not including the incombustible gas from the second chamber. The apparatus further comprises a first gas detector which is connected to the second chamber and is configured to detect the reaction gas.

According to an embodiment of the present invention, the apparatus further comprises an involving enclosure which is disposed outside the chamber housing and the gate component. The involving enclosure has a conical top.

According to an embodiment of the present invention, the involving enclosure further comprises: a third exhaust pipe connected to the conical top of the involving enclosure. The involving enclosure further comprises a second gas detector connected to the conical top of the involving enclosure and configured to detect the reaction gas.

According to an embodiment of the present invention, at least a semiconductor element comprises a wafer. The wafer comprises a semiconductor layer or an insulating layer and/or the wafer which has been treated with an ion implantation.

According to an embodiment of the present invention, the heating devices are disposed within a case of the chamber housing.

According to an embodiment of the present invention, the reaction gas is selected from a group consisting of hydrogen, isotopes of hydrogen, compounds including isotopes of hydrogen, oxygen (O₂), nitrogen (N₂), nitric oxide (NO), nitrogen dioxide (NO₂), nitrous oxide (N₂O), carbon dioxide (CO₂), carbon monoxide (CO), sulfur dioxide (SO₂), nitrogen trifluoride (NF₃), carbon tetrafluoride (CF₄), tungsten hexafluoride (WF₆), fluorine (F₂), carbonyl fluoride (COF₂), chlorine trifluoride (ClF₃), xenon fluoride (XeF₂), molybdenum fluoride (MoF6), tellurium hexafluoride (TeF₆), phosphorus trifluoride (PF₅), phosphorus pentafluoride (PF₅), arsenic fluoride (AsF₃), arsenic pentafluoride (AsF₅), hexafluoroethane (C₂F₆), octafluoropropane (C₃F₈), hexafluoro-1,3-butadiene (C₄F₆), octafluorocyclobutane (C₄F₈), octafluorocyclopentene (C₅F₈), silicon tetrafluoride (SiF₄), boron trifluoride (BF₃), germanium tetrafluoride (GeF₄), trifluoromethyl chloride (CClF₃), and chloropentafluoroethane (C₂ClF₅).

According to an embodiment of the present invention, the first chamber has a first pressure in a range of 10 atm to 300 atm.

According to an embodiment of the present invention, the first chamber has a first temperature lower than 850 ℃.

According to an embodiment of the present invention, the incombustible gas includes at least one of nitrogen, carbon dioxide and inert gas.

According to an embodiment of the present invention, the second chamber has a second pressure greater than the first pressure.

According to the another aspect of the present invention, providing a second apparatus includes a chamber housing, a gate component. The chamber housing has an opening. The gate component includes a main body, a first flange, a first sealing element, a second flange element and a second sealing element. The first flange is disposed between the main body and an inner surface of the chamber housing. A substrate processing space is defined by the main body, the first flange and the chamber housing. The first sealing element is disposed on the first flange. The second flange is disposed between the main body and the inner surface of the chamber housing. The second flange overlaps the first flange in a plan view. A clearance space is defined by the main body, the first flange, the second flange and the chamber housing. The second sealing element is disposed on the second flange.

According to an embodiment of the present invention, the substrate processing space has a first pressure in a range of 10 atm to 300 atm.

According to an embodiment of the present invention, the first chamber has a first temperature lower than 850 ℃.

According to an embodiment of the present invention, the clearance space has a second pressure greater than the first pressure.

According to an embodiment of the present invention the apparatus further comprises an involving enclosure disposed outside the chamber housing and the gate component. The involving enclosure has a conical top.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate cross-sectional diagrams of an apparatus for repairing defect of a semiconductor according to some embodiments of the present invention.

FIG. 2 illustrates a cross-sectional diagram of an apparatus for repairing defect of a semiconductor according to some embodiments of the present invention.

FIG. 3 illustrates a flow chart of a method of repairing defect of a semiconductor according to some embodiments of the present invention.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range.

According to above, the present invention provides an apparatus and a method of repairing the defect of the semiconductor can perform defect repairing for the semiconductor devices at lower temperature by using the reaction gas in a supercritical fluid state in the first chamber. The design of the second chamber is used to avoid the reaction gas leakage to environment.

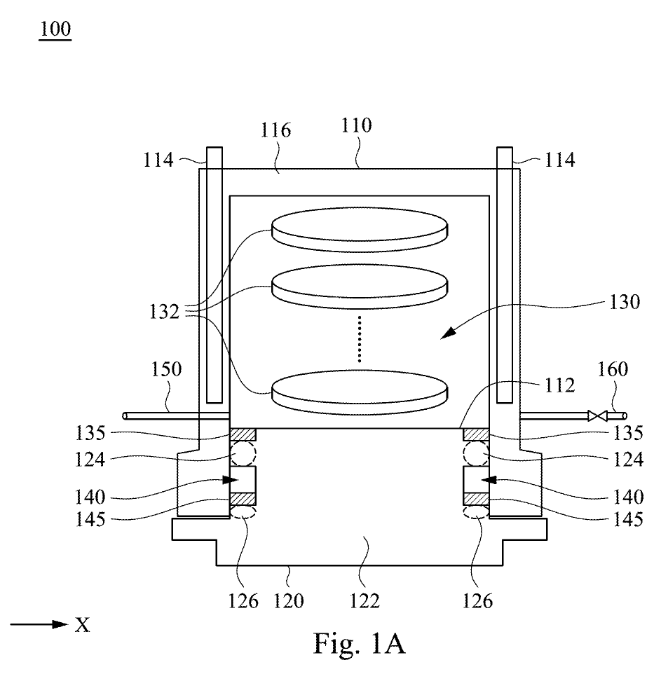

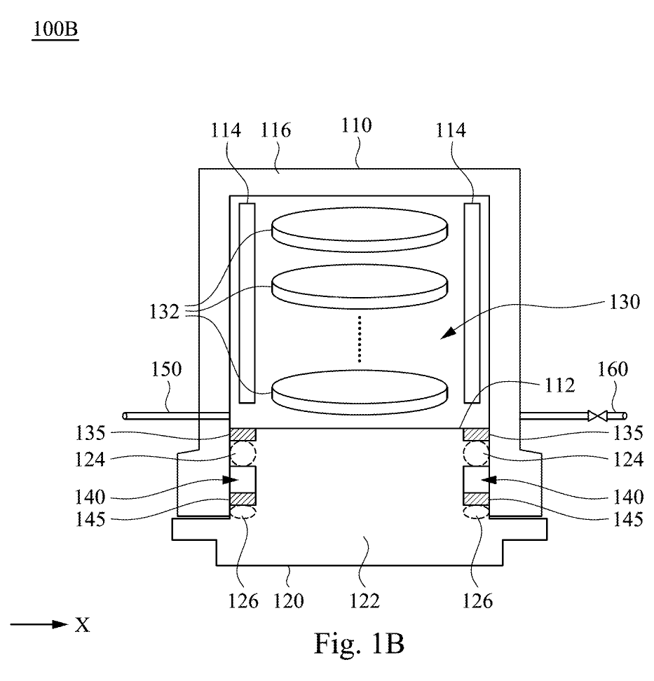

Referring to FIG. 1A, which illustrates a cross-sectional diagram of an apparatus 100 for repairing defect of a semiconductor according to some embodiments of the present invention. The apparatus 100 for repairing the defect of the semiconductor includes a chamber housing 110. The chamber housing 110 includes an opening 112 and plural of heating devices 114. The heating devices 114 are disposed within a case 116 of the chamber housing 110. In some embodiments, the heating devices 114 are disposed in holes of the case 116 to make following heating process more stable and more homogeneous; thus, a thickness of the case 116 should be modified according to sizes of the heating devices 114.

The apparatus 100 for repairing the defect of the semiconductor further includes a gate component 120. The gate component 120 is disposed at the opening 112. According to some embodiments, the gate component 120 includes a main body, a first flange 124, a second flange 126, a first sealing element 135 and a second sealing element 145. The first flange 124 is connected to a top portion of the main body 122. It is appreciated that the top portion of the main body 122 is close to the opening 112 of the chamber housing 110. An outer surface of the first flange 124 is overlapped with an inner surface of the chamber housing 110. The second flange 126 is connected to a side portion of the main body 122, and the second flange 126 is lower than the first flange 124. An outer surface of the second flange 126 is also overlapped with the inner surface of the chamber housing 110.

A room encompassed by the main body 122, the first flange 124 and the chamber housing 110 is a first chamber 130. In some embodiments, the first chamber 130 is used to accommodate at least a semiconductor element 132, such as semiconductor substrates, wafers and/or semiconductor devices, etc. In an example, the semiconductor devices include the wafer having a semiconductor layer or an insulating layer thereon or the wafer after treating with an ion implantation process. In some embodiments, the first chamber 130 is a chamber used to perform defect repairing for the semiconductor devices having defects. In an example, the defect may be interface trap in a heterogeneous interface, dislocation occurred in process of film-formation or etching, or dangling bond in bonds between molecules/ atoms.

In some embodiments, a pressure and a temperature of the first chamber 130 are a supercritical pressure and a supercritical temperature of the reaction gas, respectively. In some embodiments, the temperature of the first chamber 130 is elevated by the heating devices 114. The first sealing element 135 is disposed at a top surface of the first flange 124 to seal the first chamber 130. In some embodiments, number of the first sealing element 135 is at least one, but the number may be changed according to design of the apparatus, and it is not limited in the present invention.

The apparatus 100 for repairing the defect of the semiconductor further includes a first gas-intake pipe 150 and a first exhaust pipe 160 connected to the first chamber 130, respectively. The first gas-intake pipe 150 is configured to introduce a reaction gas into the first chamber 130, and the first exhaust pipe 160 is configured to release a gas composition and/or the reaction gas in the first chamber 130. Connection between the first gas-intake pipe 150 and the first exhaust pipe 160 and the first chamber 130 shown in FIG. 1A is only an example, but the present invention is not limited to their connection places and connection ways.

A room encompassed by the main body 122, the first flange 124, the second flange 126 of the gate component 120 and the chamber housing 110 is a second chamber 140. It is appreciated that the second chamber 140 encircles lateral wall of the main body 122 of the gate component 120. The second chamber 140 is configured to prevent the reaction gas in the first chamber 130 from leaking out to the environment directly. In some embodiments, the first chamber 130 and the second chamber 140 are in the same chamber housing 110; thus, it is faster to detect whether the reaction gas leaks out from the first chamber 130. Since the second chamber 140 is not necessary to be heated to the specific temperature, the heating devices 114 does not extend to the second chamber 140. In other words, the heating devices are not overlapped with the second chamber 140 in a direction X parallel to the second flange 126.

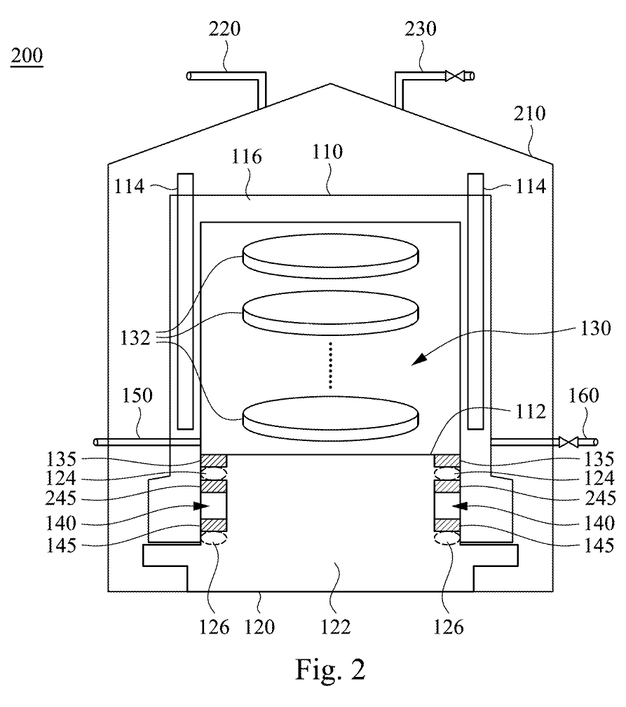

A second sealing element 145 is disposed at a top surface of the second flange to seal the second chamber 140. In some embodiments, number of the second sealing element 145 is at least one, but the number may be changed according to design of the apparatus, and it is not limited in the present invention. Referring to FIG. 2, which illustrates a cross-sectional diagram of an apparatus 200 for repairing defect of a semiconductor according to some embodiments of the present invention. In some embodiments, the gate component 120 may selectively include a third sealing element 245 to strengthen leakproofness of the second chamber 140 and avoid gas penetrating into the first chamber 130.

In some embodiments, the apparatus 100 for repairing defect of the semiconductor may selectively include a second gas-intake pipe, a second exhaust pipe and a gas detector (not shown) connected to the second chamber 140. The second gas-intake pipe is configured to introduce incombustible gas into the second chamber 140; the second exhaust pipe is configured to release the gas composition in the second chamber 140; and the gas detector is configured to detect the reaction gas in the first chamber 130. If the gas detector detects the reaction gas, the apparatus can be turned off immediately to avoid the reaction gas leaking out continuously. The second chamber 140 is introduced the incombustible gas to make the pressure of the second chamber 140 greater than the pressure of the first chamber 130; thus, the first chamber 130 is in negative pressure so that the reaction gas therein may not be easy to leak out.

Referring to FIG. 1B, which illustrates a cross-sectional diagram of an apparatus 100B for repairing defect of a semiconductor according to some embodiments of the present invention. The apparatus 100B for repairing defect of a semiconductor is similar to the apparatus 100 for repairing defect of a semiconductor, while only difference is that the heating devices 114 are disposed in the first chamber 130, thereby increasing heating efficiency in the following processes.

Referring to FIG. 2 again, in some embodiments, the apparatus 200 for repairing defect of the semiconductor may selectively include an involving enclosure disposed outside the chamber housing 110 and the gate component 120 to further reduce risk of the reaction gas leakage out to the environment. In an example, the involving enclosure 210 has a conical top. In some embodiments, the involving enclosure 210 further includes a third exhaust pipe 230 and a gas detector 220 connected to the involving enclosure 210. Generally, the reaction gas of the process of repairing defect of a semiconductor is hydrogen, which is lighter than air; thus, the third exhaust pipe 230 and the gas detector 220 are preferably connected to the conical top of the involving enclosure 210. In some embodiments, a room between the involving enclosure 210 and the chamber housing 110 is in an ambient condition, which is referring to a room temperature and a room pressure.

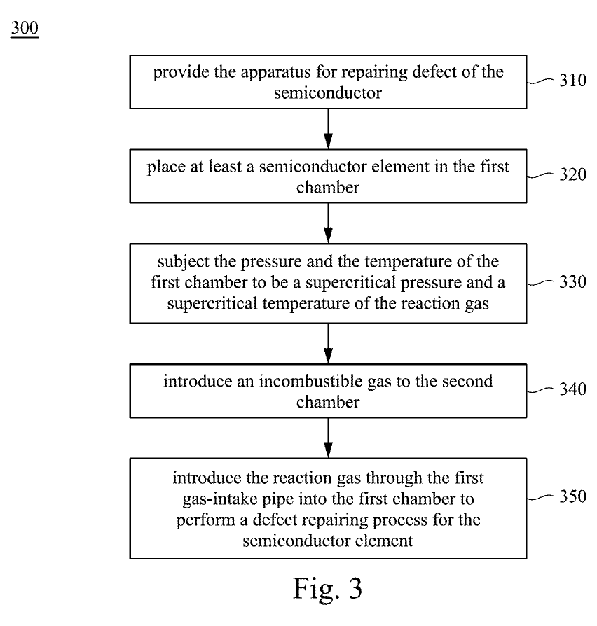

FIG. 3 illustrates a flow chart of a method 300 of repairing defect of a semiconductor according to some embodiments of the present invention. First, operation 310 is performed to provide the apparatus 100 for repairing defect of the semiconductor (or the apparatus 200 for repairing defect of the semiconductor). Referring to FIGS. 1A (or 1B or 2) and 3 simultaneously, subsequently, operation 320 is performed to place at least a semiconductor element 132 in the first chamber 130. In some embodiments, the semiconductor element 132 has internal defects or surface defects. In a case, the semiconductor element 132 includes a semiconductor substrate, a wafer and/or a semiconductor device. In an example, the semiconductor element 132 includes a wafer with a semiconductor layer or an insulating layer formed thereon and/or the wafer treated with an ion implantation. In an embodiment, the defect may be interface trap in a heterogeneous interface, dislocation occurred in process of film-formation or etching, or dangling bond in bonds between molecules/ atoms.

Then, operation 330 is performed to subject the pressure and the temperature of the first chamber 130 to be a supercritical pressure and a supercritical temperature of the following introducing reaction gas. In some embodiments, the pressure of the first chamber 130 is 10 atm to 300 atm. In some embodiments, the temperature of the first chamber 130 is lower than 850° C, 25° C to 800° C is preferable, and 200° C to 400° C is more preferable. Compared to the conventional annealing method by using furnace tube with low pressure (lower than 1 atm, for example) and high temperature (greater than 800° C, for example), which may destroy a portion of structure of specific semiconductor element, the present invention uses the apparatus 100 for repairing defect of the semiconductor (or the apparatus 200 for repairing defect of the semiconductor) to repair the defect of the semiconductor in higher pressure and lower temperature. The supercritical pressure in the first chamber 130 may assure that the following introduced reaction gas with greater concentration; thus, even at lower temperature, the gas may diffuse into interior of the semiconductor element 132 and reactivity can be affectively improved.

Subsequently, operation 340 is performed to introduce an incombustible gas to the second chamber 140. In some embodiments, the incombustible gas includes nitrogen (N₂), carbon dioxide (CO₂) and/or inert gas (such as argon (Ar)). In some embodiments, the pressure of the second chamber 140 is greater than the pressure of the first chamber. Since the reaction gas in the first chamber 130 may be hazardous or toxic gas, the first chamber 130 should be in negative pressure; thus, it is hard for the reaction gas in the first chamber 130 to leak out.

Then, operation 350 is performed to introduce the reaction gas through the first gas-intake pipe 150 into the first chamber 130 to perform a defect repairing process for the semiconductor element. In some embodiments, the reaction gas includes hydrogen, isotopes of hydrogen, compounds including isotopes of hydrogen, oxygen (O₂), nitrogen (N₂), nitric oxide (NO), nitrogen dioxide (NO₂), nitrous oxide (N₂O), carbon dioxide (CO₂), carbon monoxide (CO), sulfur dioxide (SO₂), nitrogen trifluoride (NF₃), carbon tetrafluoride (CF₄), tungsten hexafluoride (WF₆), fluorine (F₂), carbonyl fluoride (COF₂), chlorine trifluoride (ClF₃), xenon fluoride (XeF₂), molybdenum fluoride (MoF₆), tellurium hexafluoride (TeF₆), phosphorus trifluoride (PF₃), phosphorus pentafluoride (PF₅), arsenic fluoride (AsF₃), arsenic pentafluoride (AsF₅), hexafluoroethane (C₂F₆), octafluoropropane (C₃F₈), hexafluoro-1,3-butadiene (C₄F₆), octafluorocyclobutane (C₄F₈), octafluorocyclopentene (C₅F₈), silicon tetrafluoride (SiF₄), boron trifluoride (BF₃), germanium tetrafluoride (GeF₄), trifluoromethyl chloride (CClF₃), and/or chloropentafluoroethane (C₂ClF₅). The reaction gas is selected according to the semiconductor element 132. For example, if the semiconductor element 132 includes silicon, the reaction gas may select hydrogen, isotopes of hydrogen or compounds including isotopes of hydrogen, and hydrogen is preferable.

According to above, the present invention provides the apparatus and the method of repairing defect of the semiconductor, which introduce the reaction gas into the first chamber with a specific temperature and a specific pressure, thereby performing the defect repairing process to the semiconductor element in the first chamber at a lower temperature. Moreover, the disposition of the second chamber is used to avoid the reaction gas leaking out to the environment.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An apparatus, comprising:
a chamber housing having an opening and a plurality of heating devices,
a gate component disposed at the opening, the gate component including:
a main body;
a first flange disposed between a sidewall of the main body and an inner surface of the chamber housing;
a first chamber defined by an upper surface of the main body, an upper surface of the first flange and the inner surface of the chamber housing, the first chamber configured to accommodate at least a semiconductor element,
a first sealing element disposed at the upper surface of the first flange;
a second flange disposed below the first flange between the sidewall of the main body and the inner surface of the chamber housing;
a second chamber defined by the sidewall of the main body, a lower surface of the first flange, an upper surface of the second flange and the inner surface of the chamber housing, the second chamber not overlapping with the heating devices in a plan view; and
a second sealing element disposed at the upper surface of the second flange,
a first gas-intake pipe configured to introduce reaction gas to the first chamber, and
a first exhaust pipe configured to release first gas including the reaction gas and second gas not including the reaction gas from the first chamber.

2. The apparatus of claim 1, wherein the gate component further comprises a third sealing element disposed at the lower surface of the first flange.

3. The apparatus of claim 1, further comprising:
a second gas-intake pipe configured to introduce incombustible gas to the second chamber;
a second exhaust pipe configured to release third gas including the incombustible gas and forth gas not including the incombustible gas from the second chamber; and
a first gas detector connected to the second chamber and configured to detect the reaction gas.

4. The apparatus of claim 1, further comprising:
an involving enclosure disposed outside the chamber housing and the gate component,
wherein the involving enclosure has a conical top.

5. The apparatus of claim 3, further comprising:
an involving enclosure disposed outside the chamber housing and the gate component,
wherein the involving enclosure has a conical top.

6. The apparatus of claim 4,
wherein the involving enclosure further comprises:
a third exhaust pipe connected to the conical top of the involving enclosure; and
a second gas detector connected to the conical top of the involving enclosure and configured to detect the reaction gas.

7. The apparatus of claim 5, wherein the involving enclosure further comprises:
a third exhaust pipe connected to the conical top of the involving enclosure; and
a second gas detector connected to the conical top of the involving enclosure and configured to detect the reaction gas.

8. The apparatus of claim 1, wherein the at least a semiconductor element comprises a wafer, and the wafer comprises a semiconductor layer or an insulating layer and/or the wafer has been treated with an ion implantation.

9. The apparatus of claim 1, wherein the heating devices are disposed within a case of the chamber housing.

10. The apparatus of claim 1, wherein the reaction gas is selected from a group consisting of hydrogen, isotopes of hydrogen, compounds including isotopes of hydrogen, oxygen (O₂), nitrogen (N₂), nitric oxide (NO), nitrogen dioxide (NO₂), nitrous oxide (N₂O), carbon dioxide (CO₂), carbon monoxide (CO), sulfur dioxide (SO₂), nitrogen trifluoride (NF₃), carbon tetrafluoride (CF₄), tungsten hexafluoride (WF₆), fluorine (F₂), carbonyl fluoride (COF₂), chlorine trifluoride (ClF₃), xenon fluoride (XeF₂), molybdenum fluoride (MoF6), tellurium hexafluoride (TeF₆), phosphorus trifluoride (PF₅), phosphorus pentafluoride (PF₅), arsenic fluoride (AsF₃), arsenic pentafluoride (AsF₅), hexafluoroethane (C₂F₆), octafluoropropane (C₃F₈), hexafluoro-1,3-butadiene (C₄F₆), octafluorocyclobutane (C₄F₈), octafluorocyclopentene (C₅F₈), silicon tetrafluoride (SiF₄), boron trifluoride (BF₃), germanium tetrafluoride (GeF₄), trifluoromethyl chloride (CClF₃), and chloropentafluoroethane (C₂ClF₅).

11. The apparatus of claim 8, wherein the first chamber has a first pressure in a range of 10 atm to 300 atm.

12. The apparatus of claim 11, wherein the first chamber has a first temperature lower than 850 ℃.

13. The apparatus of claim 3, wherein the incombustible gas includes at least one of nitrogen, carbon dioxide and inert gas.

14. The apparatus of claim 11, wherein the second chamber has a second pressure greater than the first pressure.

15. An apparatus, comprising:
a chamber housing having an opening, and
a gate component disposed at the opening, the gate component including:
a main body;
a first flange disposed between the main body and an inner surface of the chamber housing, a substrate processing space defined by the main body, the first flange and the chamber housing;
a first sealing element disposed on the first flange;
a second flange disposed between the main body and the inner surface of the chamber housing, the second flange overlapping the first flange in a plan view, a clearance space defined by the main body, the first flange, the second flange and the chamber housing; and
a second sealing element disposed on the second flange.

16. The apparatus of claim 15, wherein the substrate processing space has a first pressure in a range of 10 atm to 300 atm.

17. The apparatus of claim 16, wherein the substrate processing space has a first temperature lower than 850 ℃.

18. The apparatus of claim 16, wherein the clearance space has a second pressure greater than the first pressure.

19. The apparatus of claim 15, further comprising:
an involving enclosure disposed outside the chamber housing and the gate component,
wherein the involving enclosure has a conical top.
